(19) United States
(12) Patent Application Publication
(10) Pub. No.: US 2016/0336190 A1
(43) Pub. Date: Nov. 17, 2016

(54) FILM FORMING METHOD AND HEAT TREATMENT APPARATUS

(71) Applicants: TOKYO ELECTRON LIMITED, Tokyo (JP); TOHOKU TECHNO ARCH CO., LTD., Sendai-shi, Miyagi (JP)

(72) Inventors: Yoshiyuki KIKUCHI, Miyagi (JP); Yasuaki SAKAKIBARA, Miyagi (JP); Seiji SAMUKAWA, Miyagi (JP)

(73) Assignees: TOKYO ELECTRON LIMITED, Tokyo (JP); TOHOKU TECHNO ARCH CO., LTD., Sendai-shi, Miyagi (JP)

(21) Appl. No.: 15/111,255

(22) PCT Filed: Jan. 14, 2015
(86) PCT No.: PCT/JP2015/050778

§ 371 Date: Jul. 13, 2016

(30) Foreign Application Priority Data
Jan. 15, 2014 (JP) 2014-005030

(51) Int. Cl. H01L 21/3105; C23C 16/46; C23C 16/50; C23C 16/455; H01L 21/02; C23C 16/40

(52) U.S. Cl. CPC H01L 21/31051; H01L 21/02126; H01L 21/02274; C23C 16/401; C23C 16/50; C23C 16/455; C23C 16/46

(57) ABSTRACT

Provided is a method for forming a low dielectric constant film on a substrate placed in a processing chamber inside a processing container. The method includes: generating plasma using microwaves by supplying at least a noble gas to a plasma generation chamber, which is formed above the processing chamber inside the processing container; forming a low dielectric constant film on the substrate by supplying particles from the plasma generation chamber to the processing chamber and supplying a precursor gas to the processing chamber through a shield unit provided between the plasma generation chamber and the processing chamber, the shield unit having a plurality of openings configured to communicate the plasma generation chamber with the processing chamber, and having a shielding property against ultraviolet light; and then, performing a heat treatment on the substrate.

### TECHNICAL FIELD

### Cross Reference to Related Applications

This application claims the priority benefit of Japanese Patent Application No. 2014-005030 filed on Jan. 15, 2014 in the Japan Patent Office, the disclosure of which is incorporated herein by reference.

The present disclosure relates to a film forming method and a heat treatment apparatus.

### BACKGROUND

In semiconductor devices, a so-called damascene structure in which a wire is formed in an interlayer insulation film is used. Recently, as the integration density and the speed operation of semiconductor devices have been increased, a low dielectric constant film (low-k film) has been studied in order to reduce capacity between wires.

As a method for forming such a low-k film, a technology has been proposed in which a precursor gas is irradiated with a neutral particle beam. In this technology, a plasma generation chamber, in which plasma of a noble gas is excited, and a processing chamber, which is supplied with the precursor gas, are separated from each other, and a shield unit is provided between the plasma generation chamber and the processing chamber. The shield unit is provided with a plurality of openings for communicating the plasma generation chamber and the processing chamber with each other. The shield unit shields ultraviolet light, generated in the plasma generation chamber, and neutralizes ions passing through the openings by supplying electrons to the ions. In this technology, the precursor gas is irradiated with particles neutralized by the shield unit, i.e. neutral particles (so-called irradiation of neutral particle beam energy) such that methyl is separated from a methoxy-group in a molecule of the precursor gas. By this, molecules generated from the precursor gas are polymerized on a substrate such as, for example, a wafer (e.g., a semiconductor wafer) such that a SiCO film, which is a low dielectric constant film, is formed on the substrate (Patent Document 1).

### PRIOR ART DOCUMENT

### Patent Document

Patent Document 1: Japanese Patent Laid-Open Publication No. 2009-290026

### DISCLOSURE OF THE INVENTION

### Problems to be Solved

However, the inventors have found problems that, when neutral particle beam energy is dispersed or the precursor gas is diffused into the plasma used for generating neutral particles, the polymerization reaction is insufficient or impurities are mixed, thereby causing deterioration in film quality. Due to these problems, it has been difficult to form a stabilized film.

The present disclosure has been made in consideration of the above problems, and an object of the present disclosure is to stabilize a low dielectric constant film, which is formed on a substrate using neutral particles, compared to the related art, thereby further increasing the dielectric constant.

### Means to Solve the Problems

In order to achieve the above object, the present invention provides a method for forming a low dielectric constant film on a substrate placed in a processing chamber inside a processing container. Plasma is generated by supplying at least a noble gas to a plasma generation chamber, which is formed above the processing chamber inside the processing container, and using microwaves. Then, a low dielectric constant film is formed on the substrate by supplying particles from the plasma generation chamber to the processing chamber and supplying a precursor gas to the processing chamber via a shield unit provided between the plasma generation chamber and the processing chamber, in which the shield unit has a plurality of openings configured to communicate the plasma generation chamber with the processing chamber, and has a shielding property against ultraviolet light. Thereafter, a heat treatment is performed on the substrate.

According to the present invention, chains in the molecular structure of the low dielectric constant film formed by neutral particles may be increased in length, which may further stabilize the low dielectric constant film, and may further improve a dielectric constant.

In another aspect, the present invention provides a heat treatment apparatus directly or indirectly connected to a film forming apparatus, which forms a low dielectric constant film, by neutral particles, on a substrate placed in a processing chamber inside a processing container, and performing a heat treatment on the substrate after the low dielectric constant film is formed by the neutral particles. The film forming apparatus includes the processing container configured to divide a space including a plasma generation chamber and the processing chamber below the plasma generation chamber, a placing table installed in the processing chamber, a first gas supply system configured to supply at least a noble gas to the plasma generation chamber, a dielectric window installed to seal the plasma generation chamber, an antenna configured to supply microwaves to the plasma generation chamber through the dielectric window, a second gas supply system configured to supply a precursor gas to the processing chamber, and a shield unit provided between the plasma generation chamber and the processing chamber, in which the shield unit has a plurality of openings configured to communicate the plasma generation chamber with the processing chamber, and also has a shielding property against ultraviolet light.

The heat treatment apparatus includes a container configured to receive the substrate having the low dielectric constant film formed by the film forming apparatus, and a heating device configured to heat the substrate inside the container.

The heat treatment apparatus may further include a bias power source configured to supply a bias power to the shield unit so as to draw ions generated in the plasma generation chamber to the shield unit into the shield unit. It is assumed that, as the precursor gas is irradiated with the particles passing through the shield unit by the bias power applied to the shield unit, the length of chains of polymers in the low dielectric constant film is increased so that the orientation of the polymers is further deteriorated. By this, the relative dielectric constant of the lower dielectric constant film may be further reduced.

The first gas supply system may supply hydrogen gas, along with the noble gas, to the plasma generation chamber. As the length of chains of polymers is further increased by hydrogen supplied to the processing chamber and the dangling bond of polymers is reduced by the supply of hydrogen, the relative dielectric constant of the low dielectric constant film may be further reduced, and in addition, the current leakage property of the low dielectric constant film may be improved.

The second gas supply system may supply toluene gas, along with the precursor gas, to the processing chamber. By this, the relative dielectric constant and polarization rate may be further reduced.

### Effect of the Invention

According to the present disclosure, when a film is formed on a substrate using neutral particles, it is possible to increase a dielectric constant by forming a stabilized film compared to the related art.

### BRIEF DESCRIPTION OF THE DRAWINGS

FIG. 1 is a vertical sectional view schematically illustrating a configuration of a film forming apparatus so as to perform a film forming method according to an exemplary embodiment.

FIG. 2 is a plan view of a slot plate used in the film forming apparatus of FIG. 1.

FIG. 3 is a partial vertical sectional view schematically illustrating a film forming system including the film forming apparatus of FIG. 1.

FIG. 4 is an explanatory view schematically illustrating the shape of a shield unit for describing a method for forming a low dielectric constant film by the film forming apparatus of FIG. 1.

FIG. 5 is an explanatory view schematically illustrating a linear structure in the film when the low dielectric constant film is formed by the film forming apparatus of FIG. 1.

FIG. 6 is an explanatory view schematically illustrating a network structure and a cage structure, which may be included in the low dielectric constant film.

FIG. 7 is an explanatory view schematically illustrating a main chain bond by an annealing treatment.

FIG. 8 is a graph illustrating variation in dielectric constant before and after annealing.

FIG. 9 is a graph illustrating measured results of FTIR for the representation of variation in the growth of a main chain before and after annealing.

### DETAILED DESCRIPTION TO EXECUTE THE INVENTION

Hereinafter, exemplary embodiments will be described with reference to the accompanying drawings. Meanwhile, in the respective drawings, the same components or components having the same function are designated by the same reference numerals.

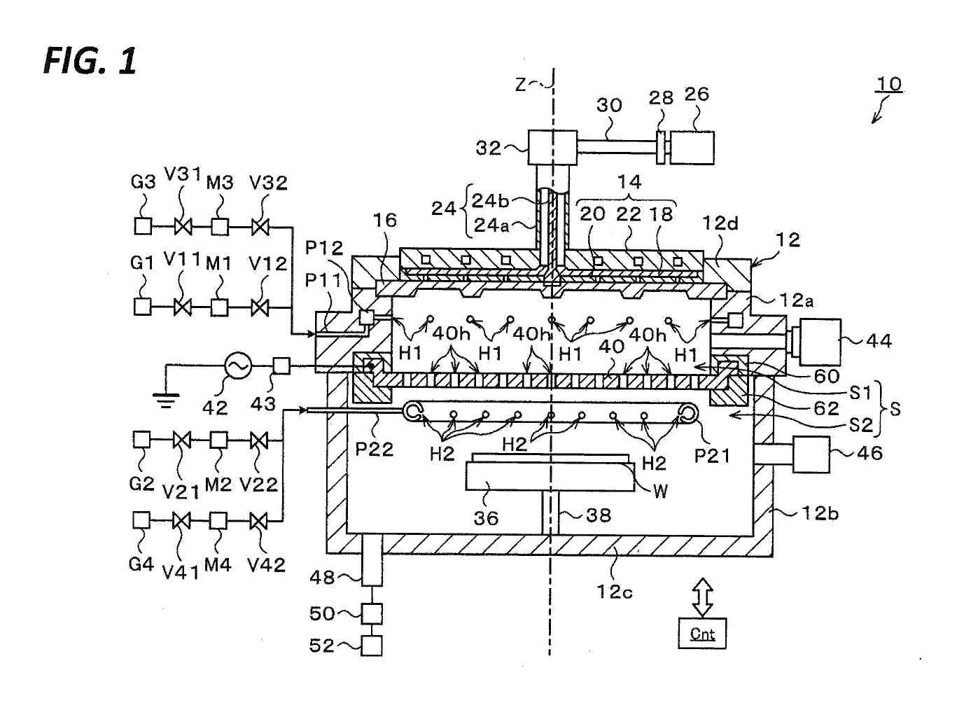

First, a film forming apparatus to perform a film forming processing will be described. FIG. 1 is a vertical sectional view schematically illustrating a film forming apparatus to perform a film forming method according to an exemplary embodiment. The film forming apparatus 10 illustrated in FIG. 1 includes a processing container 12. The processing container 12 is a substantially cylindrical container, which extends in a direction in which the Z-axis extends (hereinafter referred to as “the Z-axis direction”), and defines a space S therein. The space S includes a plasma generation chamber S1 and a processing chamber S2 formed under the plasma generation chamber S1.

The processing container 12 includes a first sidewall 12a, a second sidewall 12b, a bottom portion 12c, and a top portion 12d. These members constituting the processing container 12 are connected to a ground potential.

The first sidewall 12a has a substantially cylindrical shape, which extends in the Z-axis direction, and defines the plasma generation chamber S1 therein. Gas lines P11 and P12 are provided in the first sidewall 12a. The gas line P11 extends from an outer surface of the first sidewall 12a and is connected to the gas line P12. The gas line P12 is provided in the first sidewall 12a in an annular form centering on the Z-axis. The gas line P12 communicates with a plurality of injection holes H1 to inject a gas to the plasma generation chamber S1.

A gas source G1 is connected to the gas line P11 through a valve V11, a mass flow controller M1, and a valve V12. The gas source G1 is a gas source of a noble gas (e.g., a gas source of Ar gas). The gas source G1, the valve V11, the mass flow controller M1, the valve V12, the gas lines P11 and P12, and the injection holes H1 constitute a first gas supply system. The first gas supply system controls the flow rate of the noble gas from the gas source G1 in the mass flow controller M1, and supplies the noble gas, having the controlled flow rate, to the plasma generation chamber S1.

A gas source G3 may be connected in parallel to the gas line P11 through a valve V31, a mass flow controller M3, and a valve V32. The gas source G3 is a gas source of hydrogen gas (H₂ gas). The flow rate of hydrogen gas from the gas source G3 is controlled by the mass flow controller M3, and the hydrogen gas, having the controlled flow rate, is supplied to the plasma generation chamber S1. In this case, the gas source G3, the valve V31, the mass flow controller M3, and the valve V32 constitute the first gas supply system, in conjunction with the gas source G1, the valve V11, the mass flow controller M1, the valve V12, the gas lines P11 and P12, and the injection holes H1 described above.

An annular top portion 12d is provided on the upper end of the first sidewall 12a. The top portion 12d is provided with an opening, and an antenna 14 is provided in the opening. In addition, a dielectric window 16 is provided just under the antenna 14 so as to seal the plasma generation chamber S1.

The antenna 14 supplies microwaves to the plasma generation chamber S1 through the dielectric window 16. In this exemplary embodiment, a radial line slot antenna is employed as the antenna 14. The antenna 14 includes a dielectric plate 18 and a slot plate 20. The dielectric plate 18 shortens the wavelength of microwaves, and has substantially a disc shape. The dielectric plate 18 is formed of, for example, quartz or alumina. The dielectric plate 18 is interposed between the slot plate 20 and a metallic lower surface of a cooling jacket 22. Accordingly, in this example, the antenna 14 is configured by the dielectric plate 18, the slot plate 20, and the lower surface of the cooling jacket 22.

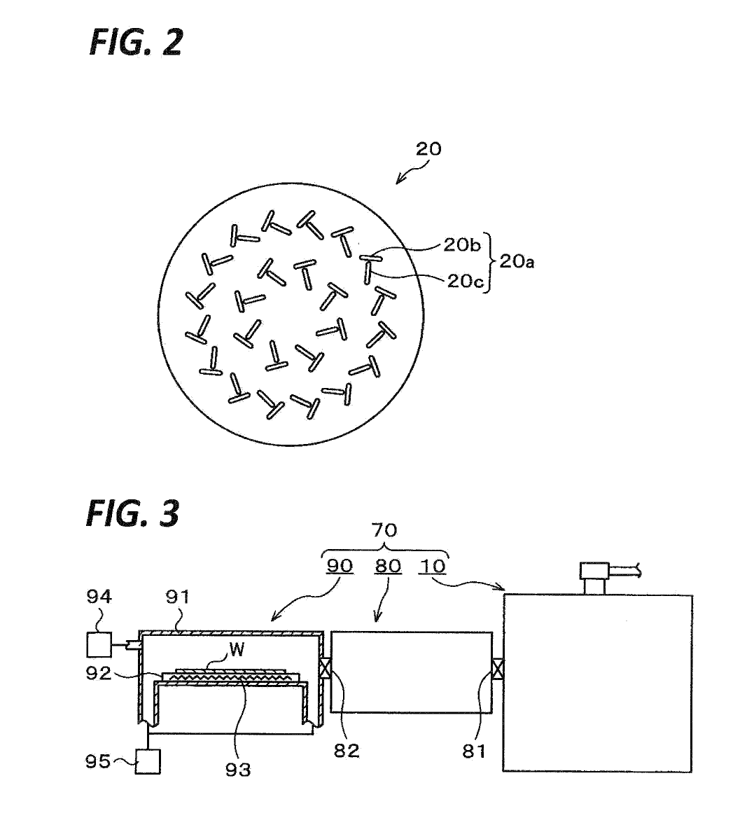

The slot plate 20 is a metal plate that has substantially a disc shape, and is provided with a plurality of pairs of slots. FIG. 2 is a plan view illustrating one example of the slot plate 20. The slot plate 20 is provided with a plurality of slot pairs 20a. The slot pairs 20a are formed at a predetermined interval in a diametric direction, and also arranged at a predetermined interval in a peripheral direction. Each slot pair 20a includes two slot holes 20b and 20c that are formed by, for example, elongated apertures or slits. The slot hole 20b and the slot hole 20c are formed and arranged to extend in intersecting or orthogonal directions.

The film forming apparatus 10 includes a coaxial waveguide 24, a microwave generator 26, a tuner 28, a waveguide 30, and a mode converter 32. The microwave generator 26 generates microwaves having a frequency of, for example, 2.45 GHz. The microwave generator 26 is connected to an upper portion of the coaxial waveguide 24 through the tuner 28, the waveguide 30, and the mode converter 32. The coaxial waveguide 24 is arranged along the Z-axis, which is the center axis of the processing container 12. The coaxial waveguide 24 includes an outer conductor 24a and an inner conductor 24b. The outer conductor 24a has a cylindrical shape, which extends in the Z-axis. A lower end of the outer conductor 24a is electrically connected to an upper portion of the cooling jacket 22 having a conductive surface. The inner conductor 24b is installed inside the outer conductor 24a. The inner conductor 24b has an approximately cylindrical shape, which extends along the Z-axis. A lower end of the inner conductor 24b is connected to the slot plate 20 of the antenna 14.

In the film forming apparatus 10, microwaves generated by the microwave generator 26 propagate to the dielectric plate 18 through the coaxial waveguide 24, and are provided to the dielectric window 16 from the slot apertures of the slot plate 20.

The dielectric window 16 has an approximately disc shape, and is formed of, for example, quartz or alumina. The dielectric window 16 is installed just below the slot plate 20. The dielectric window 16 transmits microwaves received from the antenna 14, and introduces the microwaves to the plasma generation chamber S1. By this, an electric field is generated just below the dielectric window 16, and the plasma of a noble gas is generated in the plasma generation chamber S1. In addition, in the case where hydrogen gas is supplied, along with the noble gas, to the plasma generation chamber S1, the plasma of the hydrogen gas is generated.

The second sidewall 12b is disposed below the first sidewall 12a described above so as to be successive to the first sidewall 12a. The second sidewall 12b has a substantially cylindrical shape, which extends along the Z-axis, and defines the processing chamber S2 therein. The film forming apparatus 10 includes a placing table 36 in the processing chamber S2. The placing table 36 may support a substrate, such as, for example, a semiconductor wafer on the top surface thereof. In this example, the placing table 36 is supported by a support member 38, which extends from the bottom portion 12c of the processing container 12 in the Z-axis direction. The placing table 36 includes a known attracting and holding mechanism (not illustrated) such as, for example, an electrostatic chuck, and a known temperature control mechanism (not illustrated) such as, for example, a heater.

In the processing chamber S2, a gas line P21 formed in an annular form about the Z-axis is installed above the placing table 36. The gas line P21 is provided with a plurality of injection holes H2 to inject a gas to the processing chamber S2. The gas line P21 is connected to a gas line P22, which and extends to the outside of the processing container 12 through the second sidewall 12b. The gas line P22 is connected to a gas source G2 through a valve V21, a mass flow controller M2, and a valve V22. The gas source G2 is a gas source of a precursor gas, and supplies, for example, 1,3-dimethoxytetramethlydisiloxane (DMOTMDS) gas. The gas source G2, the valve V21, the mass flow controller M2, the valve V22, the gas line P21, the gas line P12, and the injection holes H2 constitute a second gas supply system.

The second gas supply system controls the flow rate of precursor gas from the gas source G2 in the mass flow controller M2, and supplies the precursor gas, having the controlled flow rate, to the processing chamber S2. Meanwhile, all the gases having SiO in their molecular structure and a methyl group (e.g. MTMOS, di-iso-propyl-dimethoxysilane and isobutyl-dimethyl-methoxysilane), all the gases having a ring structure in their molecular structure (e.g. dimethoxysilacyclohexane, dimethyl-silacyclohexane, and 5-silaspiro[4,4]nonane), and all the gases having, for example, a benzene ring or cyclopentane in their molecular structure, which is easily broken by plasma (e.g. dicyclopentyl-dimethoxysilane) may be used as the precursor gas supplied to the processing chamber S2 by the second gas supply system.

A gas source G4 may be connected to the gas line P22 through a valve V41, a mass flow controller M4, and a valve V42. The gas source G4 is, for example, a gas source of toluene. The flow rate of toluene gas from the gar source G4 is controlled by the mass flow controller M4, and the toluene gas, having the controlled flow rate, is supplied to the processing chamber S2. In this case, the gas source G4, the valve V41, the mass flow controller M4, and the valve V42 may constitute the second gas supply system, in conjunction with the gas source G2, the valve V21, the mass flow controller M2, the valve V22, the gas lines P21 and P22, and the injection holes H2 described above.

In the film forming apparatus 10 according to the exemplary embodiment, the shield unit 40 is installed between the plasma generation chamber S1 and the processing chamber S2. The shield unit 40 is a member having an approximately disc shape, and divides the space S into upper and lower regions so as to form the plasma generation chamber S1 and the processing chamber S2. The shield unit 40 is provided with a plurality of openings 40h to communicate the plasma generation chamber S1 and the processing chamber S2 with each other.

The shield unit 40 is supported by, for example, the first sidewall 12a. In an exemplary embodiment, the shield unit 40 is interposed between an insulation member 60 and an insulation member 62, and is supported by the first sidewall 12a with the insulation members 60 and 62 being interposed therebetween. Accordingly, in the exemplary embodiment, the shield unit 40 is electrically separated from the first sidewall 12a. The shield unit 40 may be connected to a bias power source 42, which serves to supply a bias power to the shield unit 40. The bias power source 42 may be a power source to generate a high-frequency bias power. In the exemplary embodiment, the bias power source 42 supplies the high-frequency bias power to the shield unit 40 in order to introduce ions, generated in the plasma generation chamber S1, to the shield unit 40. In this case, a matcher 43 having a matching circuit to match an output impedance of the bias power source 42 with an impedance at the load side, i.e. the shield unit 40 side may be provided between the bias power source 42 and the shield unit 40. Meanwhile, a DC bias power may be supplied to the shield unit 40 using a direct current (DC) power of the bias power source 42.

The shield unit 40 may be formed of a material that does not transmit ultraviolet light, and has an ability to shield ultraviolet light generated in the plasma generation chamber S1. When the ions generated in the plasma generation chamber S1 are reflected by the inner surfaces of the holes that form the openings 40h to thereby pass through the opening 40h, the shield unit 40 provides the ions with electrons. By this, the shield unit 40 neutralizes the ions, and the neutralized ions, i.e. neutral particles are discharged to the processing chamber S2. In the exemplary embodiment, the shield unit 40 is formed of graphite. Of course, the present disclosure is not limited thereto, and the shield unit 40 may be configured as an aluminum-made member, or an aluminum-made member having a surface subjected to an alumite treatment or a surface formed with an yttria film.

When the bias power is provided to the shield unit 40, the ions generated in the plasma generation chamber S1 are accelerated toward the shield unit 40. As a result, the speed of particles passing through the shield unit 40 is increased.

In the present exemplary embodiment, the shield unit 40 has, for example, a thickness of 10 mm and a diameter of 40 cm. The diameter of the shield unit 40 is defined as the diameter of a surface that comes into contact with the plasma generation chamber S1. In addition, in the exemplary embodiment, the openings 40h of the shield unit 40 has a diameter of 1 mm. In addition, in the exemplary embodiment, the opening rate of the shield unit 40 is 10%. The opening rate of the shield unit 40 is defined as the ratio of the area occupied by the opening 40h to the area of the surface that comes into contact with the plasma generation chamber S1. Meanwhile, the opening rate may be within a range of 5% to 10%.

As described above, the film forming apparatus 10 may be provided with a shield unit 40 having a diameter of 40 cm or more so that the film forming apparatus 10 may form a film on a wafer W having a diameter of 8 inches or more. The shield unit 40 having such a large diameter has a large conductance. Specifically, the conductance C of the shield unit 40 is defined as follows.

C=¼×v×A (1)

In Equation (1), v is the average speed of molecules, and A is represented as follows.

A=π×¼×D²×B (2)

In Equation (2), D is the diameter of the shield unit 40, and B is the opening rate. As is evident from Equation (1) and Equation (2), when the diameter of the shield unit 40 is increased in order to form a film on the wafer W having a large diameter, the conductance of the shield unit 40 is increased in proportion to the square of the radius. Accordingly, in the film forming apparatus 10, it is necessary to suppress the precursor gas supplied to the processing chamber S2 from being diffused to the plasma generation chamber S1 through the shield unit 40.

Therefore, in the film forming apparatus 10, for example, the pressure within the plasma generation chamber S1 is set to four times or more the pressure of the processing chamber S2. That is, the pressure ratio is set to 4 or more. In addition, the diffusion factor is set to 0.01 or less. Here, the diffusion factor is defined as an increase in pressure in the plasma generation chamber S1 in Pascal unit when the flow rate of precursor gas supplied to the processing chamber S2 is increased by 1 sccm. The diffusion factor may be acquired from the gradient of a graph, which represents the relationship between the flow rate of precursor gas and the increase in pressure in the plasma generation chamber in the state in which the noble gas is supplied to the plasma generation chamber S1 and the flow rate of precursor gas supplied to the processing chamber S2 is increased. Although the diffusion factor partially depends on the pressure ratio, it also depends on, for example, the conductance of the shield unit 40, the flow rate of noble gas, and the flow rate of precursor gas.

In the present exemplary embodiment, the film forming apparatus 10 includes a pressure gauge 44 to measure a pressure in the plasma generation chamber S1 and a pressure gauge 46 to measure a pressure in the processing chamber S2. In addition, in the film forming apparatus 10, a pressure regulator 50 and a decompression pump 52 are connected to an exhaust pipe 48, which is connected, at the bottom portion 12c, to the processing chamber S2. The pressure regulator 50 and the decompression pump 52 constitute an exhaust apparatus. In the film forming apparatus 10, based on the pressures measured by the pressure gauges 44 and 46, the flow rate of noble gas is regulated by the mass flow controller M1, and the flow rate of precursor gas is regulated by the mass flow controller M2. In addition, the pressure regulator 50 may regulate an exhaust air flow. By this, the film forming apparatus 10 may set the pressure ratio and the diffusion factor described above.

As illustrated in FIG. 1, in the present exemplary embodiment, the film forming apparatus 10 includes a controller Cnt. The controller Cnt may be a controller such as, for example, a programmable computer device. The controller Cnt may control each component of the film forming apparatus 10 using a recipe-based program. For example, the controller Cnt may control the supply and supply-stop of the noble gas by sending a control signal to the valves V11 and V12, and may control the flow rate of noble gas by sending a control signal to the mass flow controller M1. In addition, the controller Cnt may control the supply and supply-stop of hydrogen gas by sending a control signal to the valves V31 and V32, and may control the flow rate of hydrogen gas by sending a control signal to the mass flow controller M3.

In addition, the controller Cnt may control the supply and supply-stop of the precursor gas by sending a control signal to the valves V21 and V22, and may control the flow rate of precursor gas by sending a control signal to the mass flow controller M2. In addition, the controller Cnt may control the supply and supply-stop of toluene gas by sending a control signal to the valves V41 and V42, and may control the flow rate of toluene gas by sending a control signal to the mass flow controller M4. In addition, the controller Cnt may control an exhaust air flow by sending a control signal to the pressure regulator 50. In addition, the controller Cnt may control the power of microwaves by sending a control signal to the microwave generator 26, and may control the supply and supply-stop of a bias power, more particularly, a bias power (e.g. RF power) to the shield unit 40 by sending a control signal to the bias power source 42.

Next, the film forming system having the film forming apparatus 10 described above will be described. FIG. 3 schematically illustrates the configuration of the film forming system 70. The film forming system 70 includes the film forming apparatus 10 described above, a load lock apparatus 80, and an annealing apparatus 90 that is a heat treatment apparatus. The film forming apparatus 10 and the load lock apparatus 80 are connected to each other via a gate valve 81, and the load lock apparatus 80 and the annealing apparatus 90 are connected to each other via a gate valve 82.

The load lock apparatus 80 is often referred to as a load lock chamber, and may be selected from among known apparatuses. That is, for example, the load lock apparatus 80 includes, within a container configured to be hermetically sealed, a placing table (not illustrated) having a substrate placed thereon, and a conveyance mechanism (not illustrated) to introduce and discharge the substrate on the placing table to and from the film forming apparatus 10 through the gate valve 81 and to and from the annealing apparatus 90 through the gate valve 82. In addition, the interior of the container of the load lock apparatus 80 may be decompressed at the same decompression degree as the processing container 12 of the film forming apparatus 10, and may also be regulated to the same decompression degree or inert gas atmosphere as the annealing apparatus 90. Therefore, a decompression device (not illustrated) to decompress the interior of the container (such as, for example, an exhaust pump) or a supply pipe (not illustrated) to supply an inert gas into the container is connected to the load lock apparatus 80.

The annealing apparatus 90 includes a placing table 92 configured to place a substrate placed thereon within a container 91. A heater 93 is provided in the placing table 92 so as to heat the substrate placed on the placing table 92 to a predetermined temperature for an annealing treatment. An inert gas supply source 94 is connected to the container 91 to create a predetermined inert gas atmosphere within the container 91, and an exhaust device 95 such as, for example, an exhaust pump, is connected to the bottom portion of the container 91 to exhaust the interior of the container 91. By this, the interior of the container 91 may have an inert gas atmosphere having, for example, a predetermined concentration and pressure.

The film forming system 70 to perform a film forming treatment according to the exemplary embodiment has the configuration described above, and in the film forming apparatus 10, a wafer W, which is formed with a predetermined low dielectric constant film thereon, passes through the load lock apparatus 80, and the low dielectric constant film is subjected to an annealing treatment in the annealing apparatus 90. Hereinafter, the processes in the respective apparatuses will be described in detail.

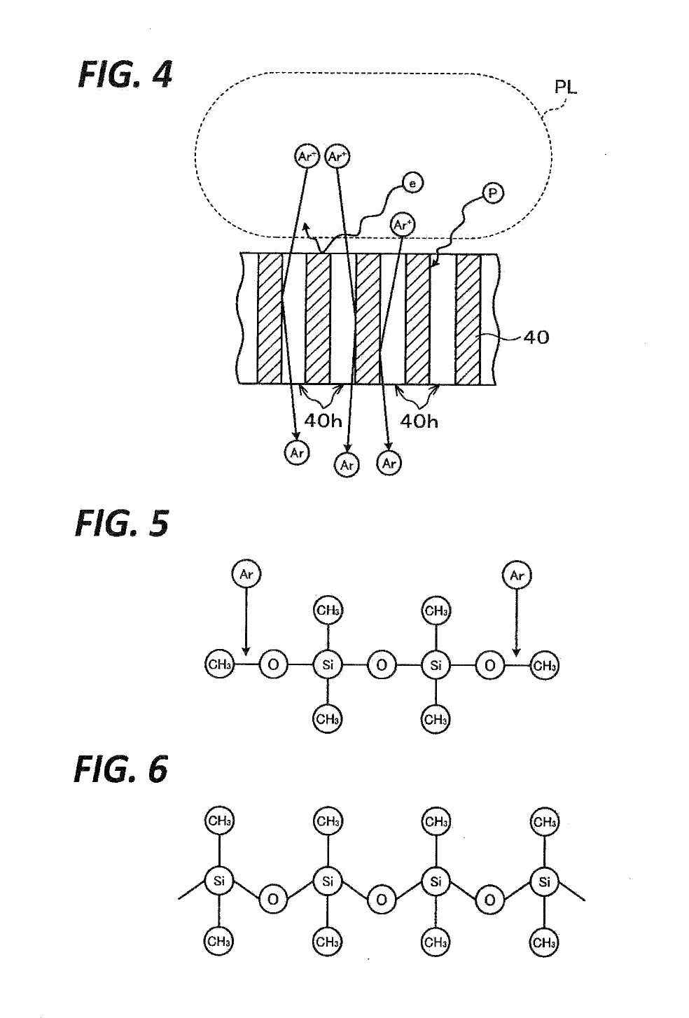

First, the principle of forming a low dielectric constant film using the film forming apparatus 10 will be described. In the film forming apparatus 10, at least a noble gas is supplied to the plasma generation chamber S1 above the shield unit 40, and microwaves are supplied to the plasma generation chamber S1. By this, as illustrated in FIG. 4, at least the plasma PL of the noble gas is generated in the plasma generation chamber S1. FIG. 4 illustrates the plasma P1 of argon gas that is a noble gas. Argon ions, electrons, and photons of ultraviolet light are generated in the plasma PL. In FIG. 4, argon ions are designated by circled “Ar+”, electrons are designated by circled “e,”, and photons are designated by circled “P.”

The electrons in the plasma PL are reflected by the shield unit 40 to thereby return to the plasma generation chamber S1. In addition, the photons are shielded by the shield unit 40. Meanwhile, the argon ions receive the electrons from the shield unit 40 by coming into contact with an inner wall surface, which divides the opening 40h, in the middle of the opening 40h. By this, the argon ions are neutralized, and thereafter discharged, as neutral particles, to the processing chamber S2. Meanwhile, in FIG. 4, the neutral particles of argon are designated by circled “Ar.”

Simultaneously, a precursor gas is supplied to the processing chamber S2. At this time, in order to reduce the diffusion of the precursor gas from the processing chamber S2 to the plasma production chamber S1, for example, the pressure ratio is set to 4 or more, and in addition, the diffusion factor is set to 0.01 or less. Accordingly, in this method, the amount of precursor gas diffused to the plasma generation chamber S1 is reduced, which may limit excessive disassociation of the precursor gas.

In addition, in the processing chamber S2, DMOTMDS gas, which is a precursor gas, is irradiated with the neutral particles of argon. As described above, in the exemplary embodiment, plasma of the noble gas is excited by microwaves supplied from a radial line slot antenna in the plasma generation chamber S1. Unlike an inductively coupled plasma source, the microwaves may have a high density even in a wide pressure band from a low pressure range to a high pressure range, and may also generate low-temperature plasma. Accordingly, particles passing through the shield unit 40 attain energy capable of limiting excessive disassociation of the precursor gas.

When the DMOTMDS gas, which is a precursor gas, is irradiated with the neutral particles, an O—CH₃ bond of a methoxy group is cut, causing a methyl group coupled to oxygen to be separated from the DMOTMDS gas. By this, as molecules generated from the precursor gas are polymerized on the wafer W, a film having a linear structure illustrated in FIG. 6 is formed on the wafer W. In the linear structure illustrated in FIG. 6, methyl-groups are symmetrically bonded to a Si atom. Accordingly, the linear structure has high molecular symmetry. In addition, because orientation polarization is canceled as the result of the structure, the structure illustrated in FIG. 6 has a low relative dielectric constant k. In addition, because a film is formed as a stack of the structure illustrated in FIG. 6, a film having a high density may be acquired.

In this point, in a low dielectric constant film generated by a conventional PE-CVD method, a film having a so-called cage structure is formed as the result of excessive disassociation of the precursor gas due to the properties of the manufacturing method. That is, in the related art, a dielectric constant is lowered by forming a porous film using a film essentially consisting of a silicon oxide. On the other hand, in the method of forming a low dielectric constant film by the film forming apparatus 10, it is possible to increase the density of the film while lowering the dielectric coefficient of the film. However, in the film having the structure illustrated in FIG. 6, there is no link between structures, and unreacted CH₃O-groups (methoxy-groups) remain. Thus, there is a possibility that the strength of the film is accordingly reduced and becomes unstable.

In the present exemplary embodiment, as described above, because the annealing treatment is performed by the annealing apparatus 90 after the film is formed by the film forming apparatus 10, the strength of the film formed by the film forming apparatus 10 may be increased so that the film may be further stabilized.

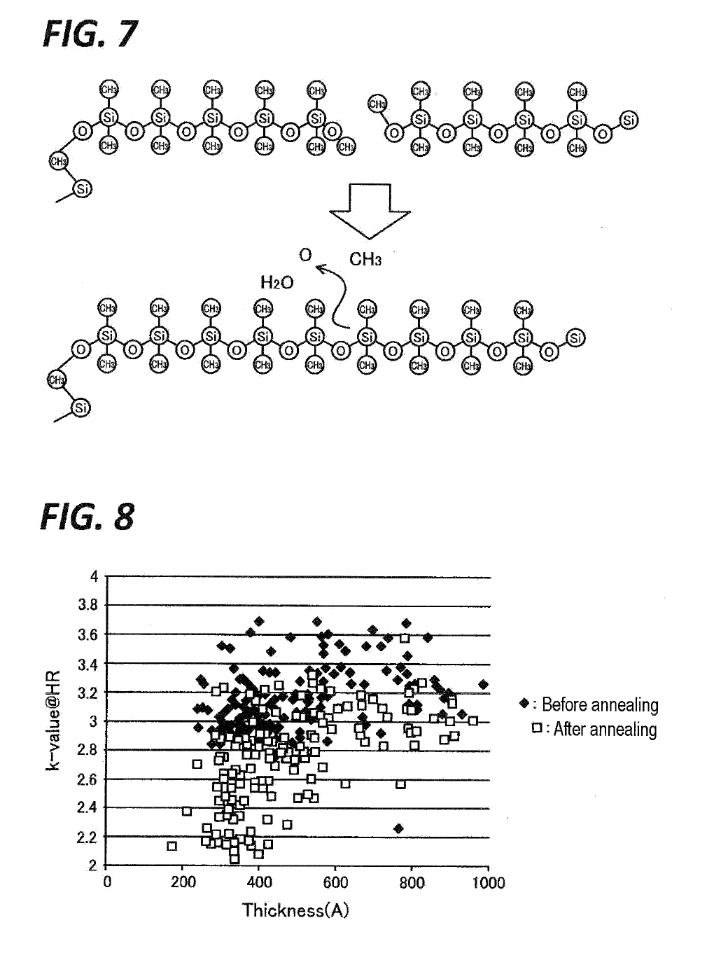

That is, in the film forming apparatus 10, after the low dielectric constant film is formed via a reaction of the neutral particles and the precursor gas, there is a case in which a linear structure having short chains may be generated in some cases as illustrated in the upper part of FIG. 7. As illustrated, it is understood that methyl-groups are coupled to oxygen at ends of some chains. By performing an annealing treatment on chains in this state, as illustrated in the lower part of FIG. 7, a re-reaction (polymerization reaction) occurs by thermal energy during the annealing, and as a result, for example, oxygen, water, and methyl-groups, which are present at the ends of chains, are removed by degassing. As a result, a long chain is generated as Si—O—Si chains are bonded. As a result, orientation polarization in molecules is reduced, which may increase a dielectric constant such that a stabilized SiCO film may be formed. In this point, it has a different mechanism from deterioration in a dielectric constant via an annealing treatment on a conventional insulation film.

That is, conventionally, a plurality of pores is formed in a film via an annealing treatment so as to form, a so-called porous film such that a dielectric constant is consequently reduced. On the other hand, as described above, the above-described exemplary embodiment re-bonds Si—O—Si chains again by an annealing treatment to form a stabilized film having no pores, which lowers the dielectric constant.

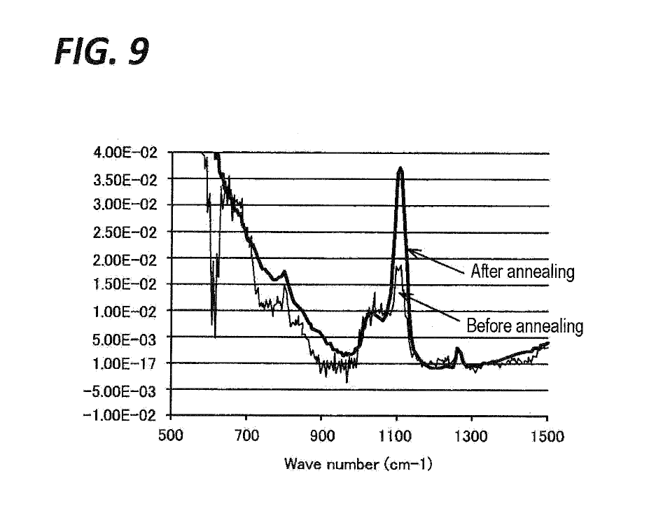

FIGS. 8 and 9 represent actual data that were obtained by performing an annealing treatment after the film was formed by the above-described film forming process. FIG. 8 illustrates a film thickness and a relative dielectric constant k. In FIG. 8, a diamond dot ⋄ represents a relative dielectric constant k before annealing, and a square dot □ represents a relative dielectric constant k after annealing. In addition, FIG. 9 illustrates investigation results of a molecular structure by Fourier transform infrared (FTIR) spectroscopy with respect to the film before and after annealing. Meanwhile, the annealing treatment was performed for one hour at the atmospheric pressure under a nitrogen gas atmosphere in a state in which the temperature of the placing table configured to place a wafer thereon was set to 350° C.

As can be seen from these results, it has been found that the dielectric constant is further improved by performing an annealing treatment after the film is formed using neutral particles as in the present exemplary embodiment. In addition, as can be seen from FIG. 9, a peak value of Si—O—Si main chains (an area of 1108 cm⁻¹) is increased, and thus, it is understood from this that the improvement in dielectric constant is realized by the stabilization of the film by a polymerization reaction and a reduction in orientation polarization in a molecule. Meanwhile, the relative dielectric constant k was 3.28 before annealing and was 2.26 after annealing. In addition, as a result of investigating the components of degassing upon the annealing treatment, CHₓ and HOₓ based reactants were measured. In addition, as a result of investigating the components of degasses before and after the annealing treatment by a thermal desorption spectroscopy (TDS), it has been confirmed that Mz=16, 17, and 18, in other words, CH₄, O, OH, and H₂O are generated at low temperatures before the annealing treatment, but reactive gases thereof at low temperatures were not measured after the annealing treatment. Thus, it is assumed that a silanol reaction was terminated after the annealing treatment. That is, it is understood that the re-reaction of unreacted portions were terminated. Meanwhile, this can be appreciated that, as a result of repeatedly performing the annealing treatment two times, the above-mentioned CHₓ and HOₓ based reactants were not measured after the second annealing treatment.

In addition, as a result of analyzing the composition of the film by X-ray photoelectron spectroscopy (XPS) after the annealing treatment, it was confirmed that there is no great variation in composition, and in addition, carbons remain to some extent. In addition, so-called film reduction did not occur.

Meanwhile, the temperature of the annealing treatment may be 150° C. or more, preferably, 350° C. or more. Further, in addition to the heater described above, UV curing or rapid thermal annealing (RTA) may be used as a heating source upon the annealing treatment. Spike annealing may also be used. In addition, although the annealing treatment was performed by the annealing apparatus 90, which is indirectly connected to the film forming apparatus 10 via the load lock apparatus 80 in the exemplary embodiment described above, the disclosure is not limited thereto, and the annealing treatment may be performed in the load lock apparatus 80. In this case, the RTA is appropriate. In addition, a heating source, such as a heater, may be installed in the film forming apparatus 10 so that the annealing treatment is performed in the film forming apparatus 10. In addition, although an atmosphere upon the annealing treatment may be under atmospheric pressure, the atmosphere may be under a vacuum atmosphere because degassing of the aforementioned components occurs during the annealing treatment. In addition, the annealing treatment may be performed under a low-oxygen atmosphere or an inert gas atmosphere.

Meanwhile, in the film forming apparatus 10 described above, a bias power may be supplied to the shield unit 40. The bias power may be a high-frequency bias power, or may be a DC bias power. With this method, the relative dielectric constant of the low dielectric constant film is further reduced. This is assumed as follows. That is, particles passing through the shield unit 40 are accelerated by the bias power applied to the shield unit 40. When DMOTDMS is irradiated with the particles accelerated by the bias power, the polymerization of molecules induced from the DMOTDMS is facilitated, thereby causing the chain length of polymers in the low dielectric constant film to be increased, which further deteriorates the orientation of the polymers. By this, it is assumed that the relative dielectric constant of the low dielectric constant film is further reduced. That is, in the film forming operation in the film forming apparatus 10, the chains of the polymers may be increased in length. Accordingly, it is understood that the dielectric constant is further reduced by performing the annealing treatment after the film forming operation.

In addition, the bias power may be supplied to the shield unit 40 and, in addition to the noble gas, hydrogen gas may be supplied to the plasma generation chamber S1. Thereby, the relative dielectric constant of the low dielectric constant film may be further reduced, and in addition, the current leakage property of the low dielectric constant film may be further improved. From this, it is believed that, when the DMOTMDS is irradiated with hydrogen (e.g. hydrogen-radicals) that has passed through the shield unit 40, silanol coupling polymerization is facilitated, thereby causing a further increase in the polymerization degree of polymers in the low dielectric constant film so that the length of polymerized chains is increased. That is, the energy of hydrogen turned into plasma forms neutral particles, thus further facilitating the polymerization reaction of precursor gas. In addition, the dangling bond of polymers is reduced by the supply of hydrogen. By this, it is assumed that the relative dielectric constant of the low dielectric constant film is further reduced, and in addition, that the current leakage property of the low dielectric constant film is improved. Meanwhile, instead of the hydrogen gas, H or OH, such as water, ethanol, or methanol, may be supplied to the precursor gas so that a gas capable of facilitating silanol coupling polymerization may be used.

In addition, toluene gas may be supplied, along with the precursor gas, to the processing chamber S2. With this method, branched chains of the precursor gas are replaced with phenyl-groups. For example, when the precursor gas is DMOTMDS, methyl-groups coupled to Si of DMOTMDS are replaced with phenyl-groups. By this, the relative dielectric constant and polarization rate of the low dielectric constant film may be further reduced.

### DESCRIPTION OF SYMBOLS

10: film forming apparatus, 12: processing container, 14: antenna, 16: dielectric window, 18: dielectric plate, 22: cooling jacket, 24: coaxial waveguide, 26: microwave generator, 28: tuner, 30: waveguide, 32: mode converter, 36: placing table, 40: shield unit, 40h: opening, 42: bias power source, 44, 46: pressure gauge, 48: exhaust pipe, 50: pressure regulator, 52: decompression pump, 70: film forming system, 80: load lock apparatus, 90: annealing apparatus, G1: gas source (noble gas), H1: injection hole, M1, M2: mass flow controller, V11, V12, V21, V22: valve, G2: gas source (precursor gas), H2: injection hole

What is claimed is:

1. A method for forming a low dielectric constant film on a substrate placed in a processing chamber inside a processing container, the method comprising:
generating plasma using microwaves by supplying at least a noble gas to a plasma generation chamber, which is formed above the processing chamber inside the processing container;
forming a low dielectric constant film on the substrate by supplying particles from the plasma generation chamber to the processing chamber and supplying a precursor gas to the processing chamber through a shield unit provided between the plasma generation chamber and the processing chamber, the shield unit having a plurality of openings configured to communicate the plasma generation chamber with the processing chamber, and having a shielding property against ultraviolet light; and
then, performing a heat treatment on the substrate.

2. The method of claim 1, wherein the low dielectric constant film is a SiCO film.

3. The method of claim 2, wherein the SiCO film has a relative dielectric constant that is less than 2.5.

4. The method of claim 1, wherein the heat treatment is performed by a heat treatment device connected to the processing container.

5. The method of claim 1, wherein the heat treatment is performed in a load lock chamber connected to the processing container.

6. The method of claim 1, wherein the heat treatment is performed in the processing container.

7. A heat treatment apparatus directly or indirectly connected to a film forming apparatus that forms a low dielectric constant film by neutral particles on a substrate placed in a processing chamber inside a processing container, the heat treatment apparatus performing a heat treatment on the substrate after the low dielectric constant film is formed by the neutral particles,
wherein the film forming apparatus includes:
the processing container configured to divide a space including a plasma generation chamber and the processing chamber below the plasma generation chamber;
a placing table provided in the processing chamber;
a first gas supply system configured to supply at least a noble gas to the plasma generation chamber;
a dielectric window provided to seal the plasma generation chamber;
an antenna configured to supply microwaves to the plasma generation chamber through the dielectric window;
a second gas supply system configured to supply a precursor gas to the processing chamber; and
a shield unit provided between the plasma generation chamber and the processing chamber, the shield unit having a plurality of openings configured to communicate the plasma generation chamber with the processing chamber, the shield unit also having a shielding property against ultraviolet light, and
wherein the heat treatment apparatus comprises:
a container configured to receive the substrate having the low dielectric constant film formed by the film forming apparatus; and
a heating device configured to heat the substrate inside the container.

8. The apparatus of claim 7, further comprising:
a decompression device configured to decompress at least an interior of the container, or an inert gas supply unit configured to create an inert gas atmosphere in the interior of the container.

9. The apparatus of claim 7, further comprising:
a bias power source configured to supply a bias power to the shield unit so as to draw ions generated in the plasma generation chamber into the shield unit.

10. The apparatus of claim 7, wherein the first gas supply system supplies hydrogen gas, along with the noble gas, to the plasma generation chamber.

11. The apparatus of claim 7, wherein the second gas supply system supplies toluene gas, along with the precursor gas, to the processing chamber.

12. The apparatus of claim 7, wherein the antenna is a radial line slot antenna.

13. The apparatus of claim 7, wherein the shield unit supplies the ions directed from the plasma generation chamber to the processing chamber with electrons.
